(19) United States
(12) Patent Application Publication
(10) Pub. No.: US 2025/0365824 A1
(43) Pub. Date: Nov. 27, 2025

(54) NOISE CANCELATION IN INDUCTION COOKING

(71) Applicant: Haier US Appliance Solutions, Inc., Wilmington, DE (US)

(72) Inventor: Nathaniel Lehrer, Louisville, KY (US)

(21) Appl. No.: 18/671,535

(22) Filed: May 22, 2024

(51) Int. Cl. H05B 6/06; G01R 19/10; H05B 6/12

(52) U.S. Cl. CPC H05B 6/062; G01R 19/10; H05B 6/1209; H05B 2213/05

(57) ABSTRACT

An induction heating system for an induction cooking appliance is provided. The induction heating system includes an induction coil system operable to inductively heat a load with an induction coil. The induction heating system further includes a noise rejection circuit configured to determine an output signal indicative of one or more induction coil parameters of the induction coil system based at least in part on a measurement signal indicative of a voltage at a first node of the induction coil system, the first node defined between the induction coil and one or more resonant capacitors of the induction coil system, and one or more noise signals indicative of a voltage at one or more second nodes of the induction coil system.

### FIELD

Example aspects of the present disclosure relate generally to induction heating systems used, for instance, in induction cooking appliances, and more particularly to determining induction coil parameters of the induction cooking appliance.

### BACKGROUND

Induction cooking appliances heat conductive cookware by magnetic induction. An induction cooking appliance applies radio frequency current to an induction heating coil to generate a strong radio frequency magnetic field on the heating coil. When a conductive vessel, such as a load (e.g., a pan), is placed over the heating coil, the magnetic field coupling from the heating coil may generate eddy currents within the vessel, causing the vessel to increase in temperature.

### SUMMARY

Aspects and advantages of embodiments of the present disclosure will be set forth in part in the following description, or can be learned from the description, or can be learned through practice of the embodiments.

One example aspect of the present disclosure is directed to an induction heating system for an induction cooking appliance. The induction heating system includes an induction coil system operable to inductively heat a load with an induction coil. The induction heating system further includes a noise rejection circuit configured to determine an output signal indicative of one or more induction coil parameters of the induction coil system based at least in part on a measurement signal indicative of a voltage at a first node of the induction coil system, the first node defined between the induction coil and one or more resonant capacitors of the induction coil system, and one or more noise signals indicative of a voltage at one or more second nodes of the induction coil system.

Another example aspect of the present disclosure is directed to a method for determining an induction coil parameter in an induction cooking appliance. The method includes determining a measurement signal indicative of a voltage at a first node of an induction coil system of the induction cooking appliance, the first node defined between two resonant capacitors. The method further includes determining one or more noise signals indicative of a voltage at one or more second nodes of the induction coil system. The method further includes determining an output signal indicative of one or more induction coil parameters of the induction coil system based at least in part on the measurement signal and the one or more noise signals.

Another example aspect of the present disclosure is directed to an induction cooking appliance. The induction cooking appliance includes a user interface including one or more user input devices. The induction cooking appliance further includes an induction heating system. The induction heating system includes an induction coil system operable to inductively heat a load with an induction coil. The induction heating system further includes a noise rejection circuit configured to determine an output signal indicative of one or more induction coil parameters of the induction coil system based at least in part on a measurement signal indicative of a voltage at a first node of the induction coil system, the first node defined between the induction coil and one or more resonant capacitors of the induction coil system, and one or more noise signals indicative of a voltage at one or more second nodes of the induction coil system.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 illustrates a perspective view of an example induction cooking appliance according to example embodiments of the present disclosure;

FIG. 2 depicts a block diagram of an example induction heating system according to example embodiments of the present disclosure;

FIG. 3 depicts a schematic implementation of an induction coil system of the induction heating system according to example embodiments of the present disclosure;

FIG. 4 provides a block diagram depicting noise cancelation according to example embodiments of the present disclosure;

FIG. 5 depicts a schematic implementation of a noise rejection circuit according to example embodiments of the present disclosure;

FIG. 6 depicts a graphical representation of example signals of the induction coil system according to example embodiments of the present disclosure;

FIG. 7 provides a method for determining an induction coil parameter in an induction cooking appliance according to example embodiments of the present disclosure; and

FIG. 8 depicts a graphical representation of example signals of the induction coil system according to example embodiments.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Induction cooking appliances may have induction heating systems configured to heat a load (e.g., a pan, cookware, vessel, etc.). The induction heating system may include one or more coils (e.g., induction coils) operable to inductively heat one or more loads with a magnetic field and an inverter system operable to supply alternating current through the coil. Induction coil parameters such as the current passing through the coil are important in deciding a variety of operational characteristics/states of the induction heating system. For example, induction coil parameters may be used to determine an output power of the induction coil or if a load is present on a coil of the induction cooking appliance.

Some induction heating systems may include systems and methods to measure induction coil parameters. For instance, some induction heating systems may use various current sensing devices (e.g., current transducers, current sensors, current transformers, Hall effect sensors, etc.) to provide a measurement signal indicative of induction coil parameters such as coil current. However, oscillations due to device and board-level parasitics (e.g., ringing) may generate noise which corrupts the measurement signal, creating inaccuracies in the measured induction coil parameters and reducing system performance. These issues may be compounded in systems where multiple coils share a power source as the ringing and interference from one channel (e.g., coil) may influence other coils of the system. The noise may be filtered with, for example, high-order filters, however this may impact the integrity of the measurement signal, further reducing system performance.

Accordingly, example aspects of the present disclosure provide systems and methods for determining an induction coil parameter through noise rejection by cancelation instead of filtering.

Example aspects of the present disclosure provide numerous technical effects and benefits. For instance, an induction heating system according to the present disclosure may provide for improved accuracy and precision in determining induction coil parameters such as the current through the coil by rejecting noise through cancellation.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (e.g., “A or B” is intended to mean “A or B or both”). The term “at least one of” in the context of, e.g., “at least one of A, B, and C” refers to only A, only B, only C, or any combination of A, B, and C. In addition, here and throughout the specification and claims, range limitations may be combined and/or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin, i.e., including values within ten percent greater or less than the stated value. In this regard, for example, when used in the context of an angle or direction, such terms include within ten degrees greater or less than the stated angle or direction, e.g., “generally vertical” includes forming an angle of up to ten degrees in any direction, e.g., clockwise or counterclockwise, with the vertical direction V.

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

The terms “coupled,” “fixed,” “attached to,” and the like refer to both direct coupling, fixing, or attaching, as well as indirect coupling, fixing, or attaching through one or more intermediate components or features, unless otherwise specified herein.

Except as explicitly indicated otherwise, recitation of a singular processing element (e.g., “a controller,” “a processor,” “a microprocessor,” etc.) is understood to include more than one processing element. In other words, “a processing element” is generally understood as “one or more processing element.” Furthermore, barring a specific statement to the contrary, any steps or functions recited as being performed by “the processing element” or “said processing element” are generally understood to be capable of being performed by “any one of the one or more processing elements.” Thus, a first step or function performed by “the processing element” may be performed by “any one of the one or more processing elements,” and a second step or function performed by “the processing element” may be performed by “any one of the one or more processing elements and not necessarily by the same one of the one or more processing elements by which the first step or function is performed.” Moreover, it is understood that recitation of “the processing element” or “said processing element” performing a plurality of steps or functions does not require that at least one discrete processing element be capable of performing each one of the plurality of steps or functions.

Referring now to the figures, example aspects of the present disclosure will be discussed in greater detail.

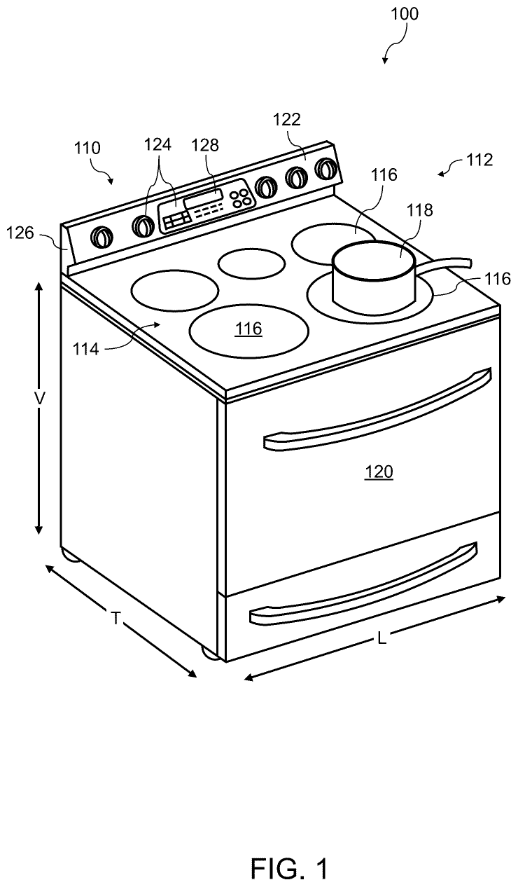

FIG. 1 depicts a perspective view of an induction cooking appliance 100. The induction cooking appliance include a cooktop 112, such as an induction cooktop. Induction cooking appliance 100 is provided by way of example only and is not intended to limit the present subject matter to the arrangement shown in FIG. 1. Thus, the present subject matter may be used with other induction cooking appliances such as oven appliances, single oven range appliances, double oven range appliances, standalone cooktop appliances, cooktop appliances without an oven, etc.

A cooking surface 114 of cooktop 112 includes one or more induction heating elements 116. As shown in FIG. 1, cooktop 112 may include a plurality of heating elements 116. The heating elements 116 are generally positioned at, e.g., on or proximate to, the cooking surface 114. For the embodiment depicted, the cooktop 112 includes five heating elements 116 spaced along cooking surface 114. However, in other embodiments, the cooktop 112 may include any other suitable shape, configuration, and/or number of heating elements 116. Each of the heating elements 116 may be induction heating elements 116, or cooktop 112 may include a combination of different types of heating elements 116. For example, in various embodiments, the cooktop 112 may include any other suitable type of heating elements 116 in addition to the induction heating element, such as a resistive heating element or gas burners, etc.

As shown in FIG. 1, a load 118 (e.g., cooking vessel), such as a pot, pan, or the like, may be placed on an induction heating element 116 to heat the load 118 and cook or heat food items placed in load 118. Induction cooking appliance 100 may also include a door 120 that permits access to a cooking chamber (not shown) of induction cooking appliance 100, e.g., for cooking or baking of food items therein. A control panel 122 (e.g., user interface) having controls 124 (e.g., user input devices) permits a user to make selections for cooking of food items. Although shown on a backsplash or back panel 126 of induction cooking appliance 100, control panel 122 may be positioned in any suitable location. Controls 124 may include buttons, knobs, and the like, as well as combinations thereof, and/or controls 124 may be implemented on a remote user interface device such as a smartphone, tablet, etc. As an example, a user may manipulate one or more controls 124 to select a temperature and/or a heat or power output for each heating element 116. The selected temperature or heat output of heating element 116 affects the heat transferred to load 118 placed on heating element 116. The control panel 122 may also include a display 128.

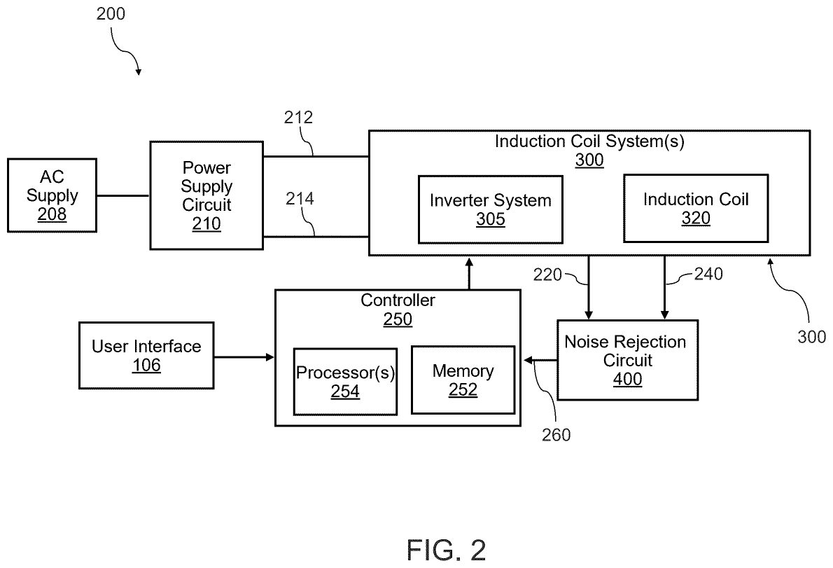

The induction cooking appliance 100 includes a control system for controlling one or more of the plurality of heating elements 116. Specifically, the control system may include a controller operably coupled to the control panel 122 and the controls 124 and display 128 thereof. The controller may be operably coupled to each of the plurality of heating elements 116 for controlling a heating level each of the plurality of heating elements 116 in response to one or more user inputs received through the control panel 122 and controls 124. The controller may also provide output to the display 128, such as an indication of a selected power level, which heating element(s) 116 is or are activated, etc. Furthermore, as will be discussed in greater detail below, the controller may further be configured to control operation of an induction heating system 200 (FIG. 2) of the induction cooking appliance 100.

Referring now to FIG. 2, a block diagram of an induction heating system 200 for an induction cooking appliance is provided. While induction heating system 200 is discussed with reference to induction cooking system 100 of FIG. 1, those of ordinary skill in the art will understand that induction heating system 200 may be used in any suitable cooking system without deviating from the scope of the present disclosure.

Induction heating system 200 generally includes a power supply circuit 210. Power supply circuit 210 may receive AC power from an AC supply 208, which may provide conventional 60 Hz 120 or 240 volt AC supplied by utility companies. Power supply circuit 210 may include rectification circuitry for rectifying the power signal from the AC supply 208. In addition, power supply circuit 210 may include filtering and power factor correction circuitry to filter the rectified power signal. In some embodiments, AC supply 208 and/or power supply circuit 210 is configured to provide AC power to multiple induction coils 320.

Induction heating system 200 further includes an induction coil system 300 operable to inductively heat a load with an induction coil 320. As shown in FIG. 2, induction coil system 300 includes an inverter system 305 and is operatively coupled to power supply circuit 210 by a high-side path 212 and a low-side path 214. In some embodiments, high-side path 212 may be defined by a bus voltage, which is supplied to induction coil system 300 by power supply circuit 210. Low-side path 214 may be defined by a ground supplied to low-side path 214 by power supply circuit 210.

Induction coil system 300 includes an induction coil 320 and an inverter system 305, such as a resonant inverter system. Coil 320, when supplied with an alternating current by inverter system 305, inductively heats the load 118 (e.g., pan, cooking vessel) or other object placed on, over, or near the coil 320. It will be understood that use of the term “load” herein is used merely as an example, and that term will generally include any object of a suitable type that is capable of being heated by an induction heating coil.

Induction heating system 200 further includes a noise rejection circuit 400. A measurement signal 220 may be provided to noise rejection circuit 400 from the induction coil system 300. Measurement signal 220 is indicative of a voltage at a first node (e.g., measurement node) of the induction heating system. One or more noise signals 240 indicative of a voltage at one or more second nodes of the induction coil system are also provided to noise rejection circuit 400 from the induction coil system 300. In some embodiments, the one or more noise signals 240 includes a high-side signal indicative of a high-side voltage (e.g., bus voltage) at a node defined by high-side path 212. Further, the one or more noise signals 240 may also include a low-side signal indicative of a low-side voltage of the induction coil system 300. Noise rejection circuit 400 is configured to determine an output signal 260 indicative of one or more induction coil parameters of the induction coil system 300 based at least in part on the measurement signal 220 and the one or more noise signals 240.

In some embodiments, induction heating system 200 further includes a controller 250. Controller 250 may be operatively coupled to induction coil system 300. Controller 250 may be configured to control the power of the induction coil 320 by controlling the switching frequency of inverter system 305. For example, controller 250 may include a microcontroller and/or gate driver to drive individual transistors or switching devices of the induction coil system 300 (e.g., inverter system 305 of induction coil system 300) with pulse-width modulated signals. Controller 250 may include memory 252 and one or more processors 254 such as microprocessors, CPUs or the like, such as general or special purpose microprocessors operable to execute programming instructions or micro-control code associated with operation of induction cooking appliance 100. Memory 252 may represent random access memory such as DRAM, or read only memory such as ROM or FLASH. In one embodiment, the processor 254 executes programming instructions stored in memory 252. Memory 252 may be a separate component from controller 250 or may be included onboard controller 250.

Controller 250 may also be operably coupled to noise rejection circuit 400. For example, noise rejection circuit 400 may provide output signal 260 to controller 250. Accordingly, controller 250 may process output signal 260 to determine operational characteristics of the induction coil system such as the power of the induction coil and/or a load presence of the induction coil (e.g., if a load is present on the induction coil). In some embodiments, controller 250 may be operatively coupled to a user interface 106.

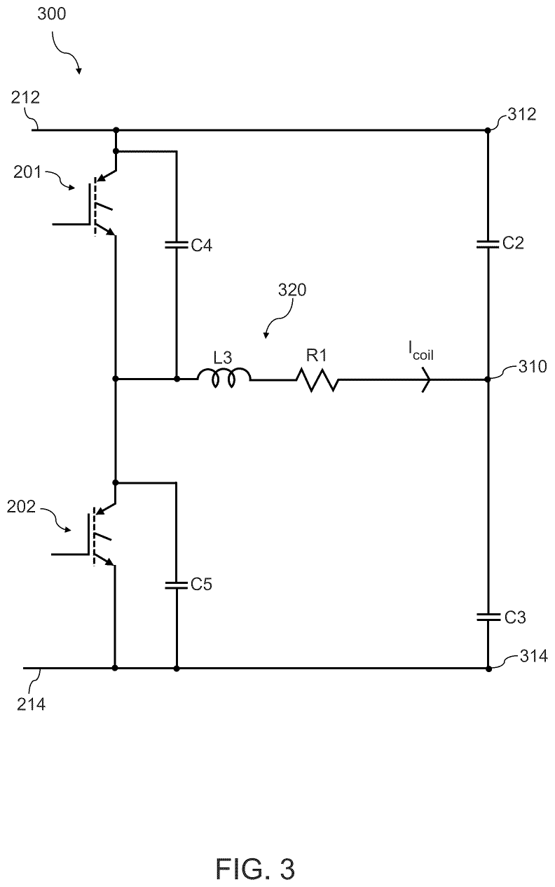

FIG. 3 depicts a schematic implementation of an induction coil system according to example embodiments of the present disclosure. Induction coil system 200 may be implemented in an induction heating system for an induction cooking appliance. For example, induction coil system 200 may be implemented in an induction heating system 200 for a induction cooking appliance 100, as shown in FIGS. 1 and 2.

Induction coil system 300 includes induction coil 320. As shown in FIG. 3, induction coil 320 and, if present, load 118 (shown in FIG. 1) is represented as an inductor (e.g., L3) and a resistor (e.g., R1). Induction coil 320 is coupled between high-side switching device 201 and low-side switching device 202. As such, switching devices 201, 202 provide alternating current to the induction heating coil 110 at a desired frequency. In some embodiments, switching devices 201, 202 may be Insulated-Gate Bipolar Transistors (e.g., IGBTs). However, other suitable switching devices (e.g., MOSFETs) may be used without deviating from the scope of the present disclosure. Switching devices 201, 202 may be configured in parallel with capacitors C4 and C5 respectively.

Induction coil system 300 further includes one or more resonant capacitors (e.g., C2 and C3). The one or more resonant capacitors may include a high-side resonant capacitor C2 and a low-side resonant capacitor C3. A measurement node 310 may be defined between the induction coil 320 and the one or more resonant capacitors (e.g., C2 and C3).

As previously described with reference to FIG. 2, induction coil system 300 may be operatively coupled to power supply circuit 210 by high-side path 212 and a low-side path 214. As shown in FIG. 3, high-side path 212 may be operatively coupled to high-side switching device 201 and high-side resonant capacitor C2. Accordingly, a high-side node 312 may be defined by high-side path 212, such as between high-side switching device 201 and high-side resonant capacitor C2.

In addition, induction coil system 300 may further be operatively coupled to power supply circuit 210 (as shown in FIG. 2) by low-side path 214. As shown, low-side path 214 may be operatively coupled to low-side switching device 202 and low-side resonant capacitor C3. A low-side node 314 may be defined by low-side path 214, such as between low-side switching device 202 and low-side resonant capacitor C3.

As shown in FIG. 3, induction coil 320 and resonant capacitors C2 and C3 may form a resonant tank. In some embodiments, measurement node 310 may be defined within the resonant tank. Further, high-side node 312 and low-side node 314 may be defined outside the resonant tank. In some embodiments, high-side node 312 may be defined by a high-side voltage (e.g., bus voltage) supplied from power supply circuit 210 (FIG. 2) while low-side node 314 may be defined by a ground. For example, high-side node 312 may be defined by a bus voltage applied to high-side path 212 by power supply circuit 210 (FIG. 2). Further, low-side node 314 may be defined by a ground applied to low-side path 214 by power supply circuit 210 (FIG. 2).

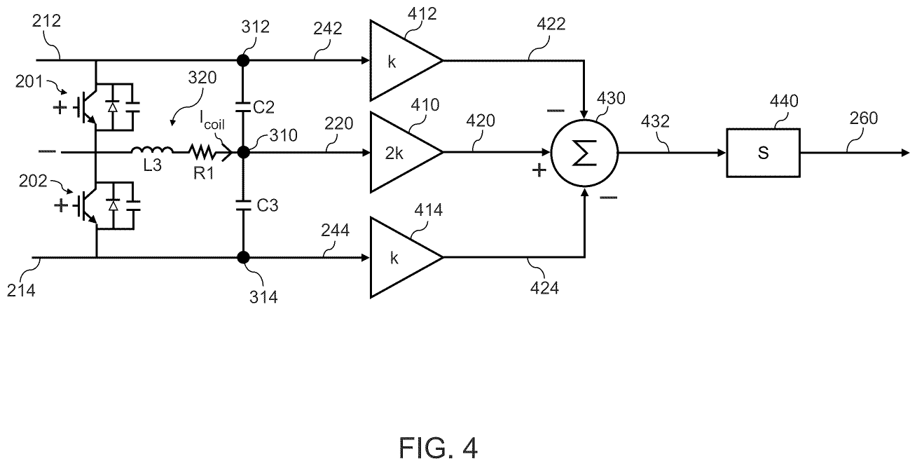

Referring now to FIG. 4, a block diagram depicting noise cancellation by a noise rejection circuit according to example embodiments of the present disclosure is provided. Specifically, FIG. 4 depicts noise cancellation in the Laplace domain that may be implemented by a noise rejection circuit according to example embodiments of the present disclosure.

As previously described, measurement node 310 may be defined between the induction coil 320 and the one or more resonant capacitors (e.g., C2 and C3). A voltage at measurement node 310 may be indicative of the current through induction coil 320 (I_{Coil}). This is due to the relationship between current (I), capacitance (C), and the rate of change in the voltage across the capacitor with respect to time (dv/dt) which is reflected by the following formula:

$$I = C * \frac{dv}{dt}$$

Furthermore, the coil current (I_{Coil}) is also expected to be approximately two times the individual resonant capacitor current (I_{CR}). As used herein, “approximately” or “about” includes values within ten percent (10%) of the nominal value. However, this simplified system model neglects disturbances injected from the bus and ground (e.g., high-side path and low-side path). When incorporating these disturbances, the voltage at measurement node 310 (Vₘₑₐₛ) may be given by integrating over time a summation of the coil current contribution

$$( \frac{1}{2 * C} * {i}_{coil} ( t ) dt ) ,$$

the bus voltage contribution

$$( \frac{{V}_{bus} ( t )}{2} + \frac{1}{2} {v}_{noise , bus} ( t ) ) ,$$

and the ground contribution

$$( \frac{1}{2} {v}_{noise , low} ( t ) ) .$$

This relationship is reflected by the following formula:

$${v}_{meas} = {\int }_{0}^{t} \frac{1}{2 * C} * {i}_{coil} ( t ) dt + \frac{{V}_{bus}}{2} + \frac{1}{2} {v}_{noise , bus} ( t ) + \frac{1}{2} {v}_{noise , low} ( t )$$

The voltage contribution from the coil current may be derived by doubling the voltage at the measurement node 310 and subtracting the high-side voltage (V_{bus}+ν_{noise,bus}) and low-side voltage (ν_{noise,low}) of the induction coil system 300. This is shown mathematically in the formula below:

$$2 * ( {\int }_{0}^{t} \frac{1}{2 * C} * {i}_{coil} ( t ) dt + \frac{{V}_{bus}}{2} + \frac{1}{2} {v}_{noise , bus} ( t ) + \frac{1}{2} {v}_{noise , gnd} ( t ) ) - ( {V}_{bus} + {v}_{noise , bus} ( t ) + {v}_{noise , low} ( t ) ) = {\int }_{0}^{t} \frac{1}{C} * {i}_{coil} ( t ) dt$$

As shown in FIG. 4, a measurement signal 220 is provided from measurement node 310. At 410, determine a doubled measurement signal 420 is determined by doubling measurement signal 220. At 412 and 414, high-side noise signal 242 and low-side noise signal 244 (e.g., noise signals 240 as shown in FIG. 2) are determined from high-side node 312 and low-side node 314 respectively. As shown at 410, 412, and 414, signals 242, 220, 244 may be scaled (e.g., multiplied) by scaling factor k by, for example, a scaling circuit of a noise rejection circuit. For example, k may be some scaling factor that allows signals 420, 422, 424 to be read by an ADC or other appropriate device.

At 430, the one or more noise signals 240 (e.g., high-side signal 422, high-side signal 422 and low-side signal 424) are subtracted from the doubled measurement signal 420 to yield signal 432. This may be done, for example, by a summation circuit of a noise rejection circuit. While one or more noise signals 240 are illustrated in FIG. 4 as being high-side signal 242 and low-side signal 244, those of ordinary skill in the art will understand that any suitable combination of noise signals 240 may be used. For example, one or more noise signals 240 may include only high-side signal 242. Accordingly, output signal 260 may be determined by subtracting only the high-side signal 242 from the doubled measurement signal 220 in some embodiments.

At 440, an output signal 260 is determined that is indicative of coil current (I_{Coil}) by differentiating signal 432 by differentiator operator s. This may be done, for example, by a differentiation circuit. As shown in FIG. 2, output signal 260 may be provided to controller 250 to determine an output power or a load presence of the induction cooking appliance. Those of ordinary skill in the art will understand that the order of scaling by scaling factor k, summation, and differentiation may be interchanged without deviating from the scope of the present disclosure as they are linear operators.

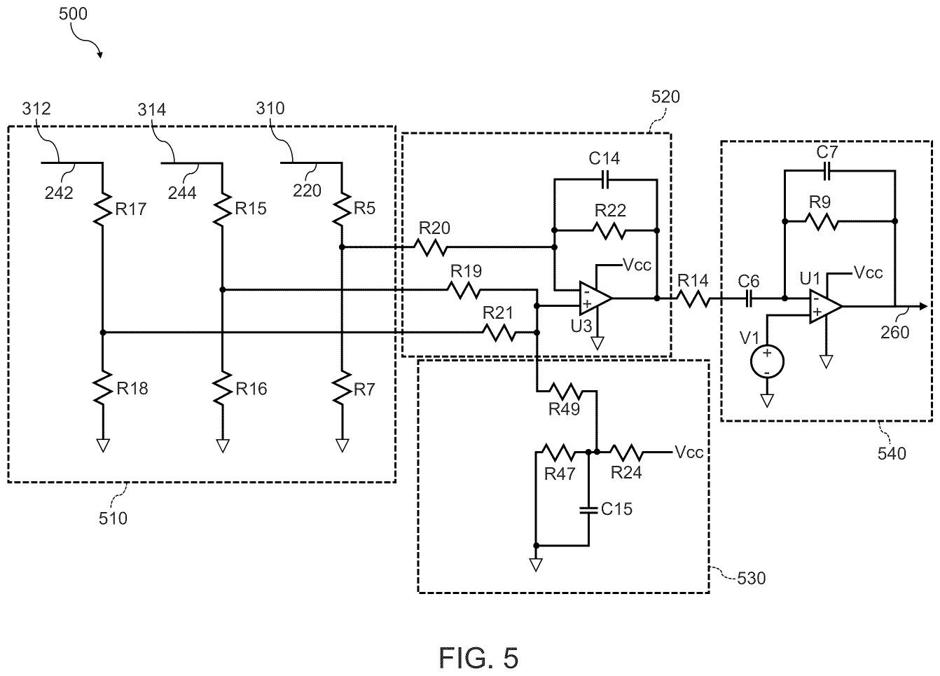

FIG. 5 provides a schematic implementation of an example noise rejection circuit 500 according to example embodiments of the present disclosure. While noise rejection circuit 500 is described with reference to induction heating system 200 as shown in FIG. 2 and induction coil system 300 as shown in FIG. 3, those of ordinary skill in the art will understand that noise rejection circuit 500 may be implemented within any suitable induction heating system. As shown below, noise rejection circuit 500 may implement noise cancelation as shown in FIG. 4.

As shown in FIG. 5, noise rejection circuit 500 may be defined by several sub-circuits. It should be noted that the arrangement of the various components and sub-circuits of noise rejection circuit 500 in FIG. 5 is for purposes of illustration and discussion. Those having ordinary skill in the art, using the disclosures provided herein, will appreciate that any suitable topology may be used without deviating from the scope of the present disclosure.

Noise rejection circuit 500 may include a scaling circuit 510 configured to scale measurement signal 220 and one or more noise signals 240 (e.g., high-side signal 242 and low-side signal 244). While one or more noise signals 240 are illustrated in FIG. 5 as being high-side signal 242 and low-side signal 244, those of ordinary skill in the art will understand that any suitable combination of noise signals 240 may be used. For example, one or more noise signals 240 may include high-side signal 242. Accordingly, output signal 260 may be determined by subtracting only the high-side signal 242 from the doubled measurement signal 220 in some embodiments.

As shown in FIG. 5, scaling circuit 510 may receive a measurement signal 220 from measurement node 310 of induction coil system 300. Scaling circuit 510 further receives one or more noise signals indicative of a voltage at one or more second nodes of the induction coil system. The one or more noise signals may include a high-side signal 242 indicative of a high-side voltage (e.g., bus voltage) of the induction coil system 300 and a low-side signal 244 indicative of a low-side voltage of the induction coil system 300.

Scaling circuit 510 may include three voltage divider circuits, each voltage divider configured to scale signals 242, 244, 220 to an appropriate voltage level. In some embodiments, scaling circuit 510 may be configured to determine a doubled measurement signal by doubling measurement signal 220. For example, resistor R7 of the voltage divider receiving measurement signal 220 may have a resistance value that is twice that of R16 and R18, while R5, R15, and R17 have equivalent resistance values. This provides the measurement signal at double the voltage of the one or more noise signals.

Noise rejection circuit 500 further includes summation circuit 520. The ratio of R22 to R19, R20, and R21 allow for scaling to be applied to the sum of signals derived from nodes 310, 312, and 314. In addition, summation circuit 520 may include operational amplifier U3. The doubled measurement signal may be an input to operational amplifier U3 along with high-side signal 242 and low-side signal 244. Specifically, operational amplifier U3 subtracts high-side signal 242 and low-side signal 244 from the doubled measurement signal. In some embodiments, summation circuit 520 may include capacitor C14 to implement a low-pass filter using operational amplifier U3.

In some embodiments, noise rejection circuit further includes an offset circuit 530. As shown in FIG. 5, offset circuit 530 may be configured to add a direct-current (DC) offset to the high-side signal 242 and low-side signal 244 in order to bias the first op-amp output to a DC level. As previously described, scaling circuit 510 may be configured to double measurement signal 220. In alternative embodiments, the measurement signal may be doubled using summation circuit 520 and offset circuit 530. For example, the ratios of R20, R22, R19, and R21 and offset circuit 530 may produce the doubling effect.

Noise rejection circuit 500 may further include a differentiation circuit 540. Differentiation circuit 540 is configured to differentiate the output signal. For example, differentiation circuit 540 may take the derivative of the signal output from, for example, summation circuit 520 to determine output signal 260. In some embodiments, a differentiation circuit 540 may provide output signal 260 to controller 250 (FIG. 2).

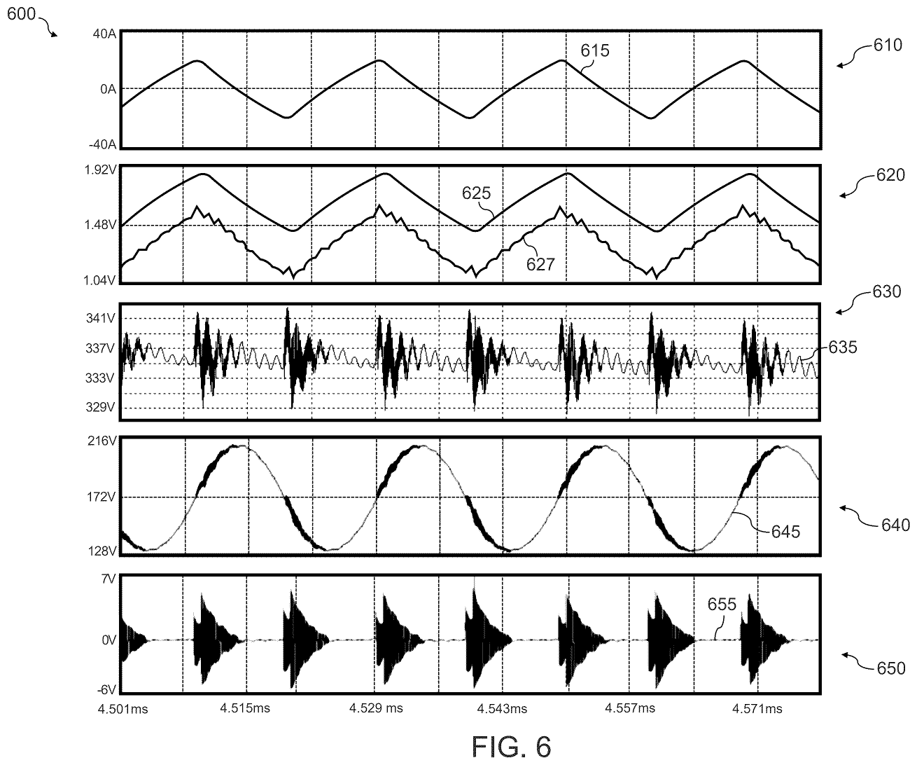

FIG. 6 provides a graphical representation of example signals 600 of an induction heating system according to example embodiments of the present disclosure. Specifically, FIG. 6 depict example signals 600 of induction coil system 300 and noise rejection circuit 500.

As shown in FIG. 6, plot 610 shows an example coil current signal 625 of the coil current (I_{Coil}) over a period of time. Plot 640 depicts an example measurement signal. As shown, the measurement signal 645 of plot 640 is indicative of a voltage at measurement node 310 as shown in FIGS. 3 and 5. As previously described, measurement node 310 may be defined between induction coil 320 and one or more resonant capacitors (e.g., C2 and C3) of induction coil system 300. Plots 630, 650 show example noise signals 635, 655 indicative of a voltage at one or more second nodes of an induction coil system. Specifically, the noise signal of plot 630 is a high-side signal indicative of a voltage at high-side node 312 (e.g., bus voltage) as shown in FIGS. 3 and 5, while the noise signal 655 of plot 650 is a low-side signal indicative of a voltage at low-side node 314. As shown in plot 640, the example measurement signal 645 includes noise produced, for example, by noise signals 635, 655.

Plot 620 depicts an example output signal 625 of noise rejection circuit 500 based on measurement signal 645 and noise signals 635, 655. As shown, output signal 625 may be an voltage signal representative of I_{Coil} shown in plot 610. Plot 620 also shows an output signal 627 of differentiation circuit 540 when only a single measurement signal is used as an input without noise rejection. As shown, output signal 625 based on the measurement signal and the one or more noise signals may provide improved noise cancellation when compared to output signal 627 based on the measurement signal only.

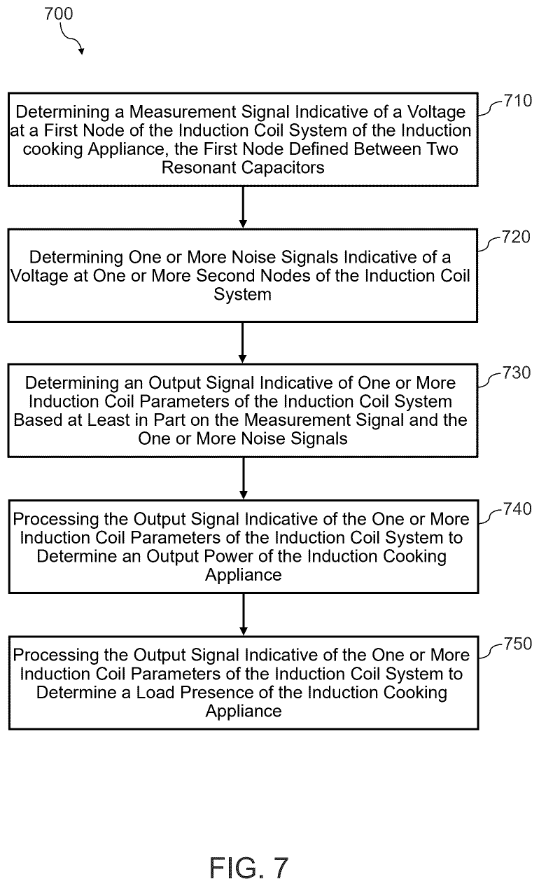

FIG. 7 provides a method for determining an induction coil parameter in an induction cooking appliance according to example embodiments of the present disclosure. Specifically, method 700 may be implemented to conduct noise cancellation as shown in FIG. 4.

At 710, method 700 includes determining a measurement signal indicative of a voltage at a first node of an induction coil system of the induction cooking appliance, the first node defined between two resonant capacitors. For example, measurement signal 220 may be determined at measurement node 310. Measurement signal 220 is indicative of a voltage at measurement node 310 defined between resonant capacitors C2 and C3.

At 720, method 700 includes determining one or more noise signals indicative of a voltage at one or more second nodes of the induction coil system For example, high-side signal 242 and low-side signal 244 may be determined at high-side node 312 and low-side node 314 respectively. In some embodiments, high-side signal 242 is indicative of a bus voltage of an induction heating system while low-side signal 244 is indicative of a low-side voltage of an induction heating system. In some embodiments, high-side node 312 is defined between high-side resonant capacitor C2 and high-side switching device 201 of an induction coil system. Similarly, low-side node 314 may be defined between low-side resonant capacitor C3 and low-side switching device 202.

At 730, method 700 includes determining an output signal indicative of one or more induction coil parameters of the induction coil system based at least in part on the measurement signal and the one or more noise signals. For example, output signal 260 may be indicative of an induction coil parameter such as coil current (I_{Coil}).

In some embodiments, method 700 includes, at 740, processing the output signal indicative of the one or more induction coil parameters of the induction coil system to determine an output power of the induction cooking appliance. For example, controller 250 may be configured to process output signal 260 to determine an output power of the induction cooking appliance.

In some embodiments, method 700 includes, at 750, processing the output signal indicative of the one or more induction coil parameters of the induction coil system to determine a load presence of the induction cooking appliance. For example, controller 250 may be configured to process output signal 260 to determine a load presence of the induction cooking appliance.

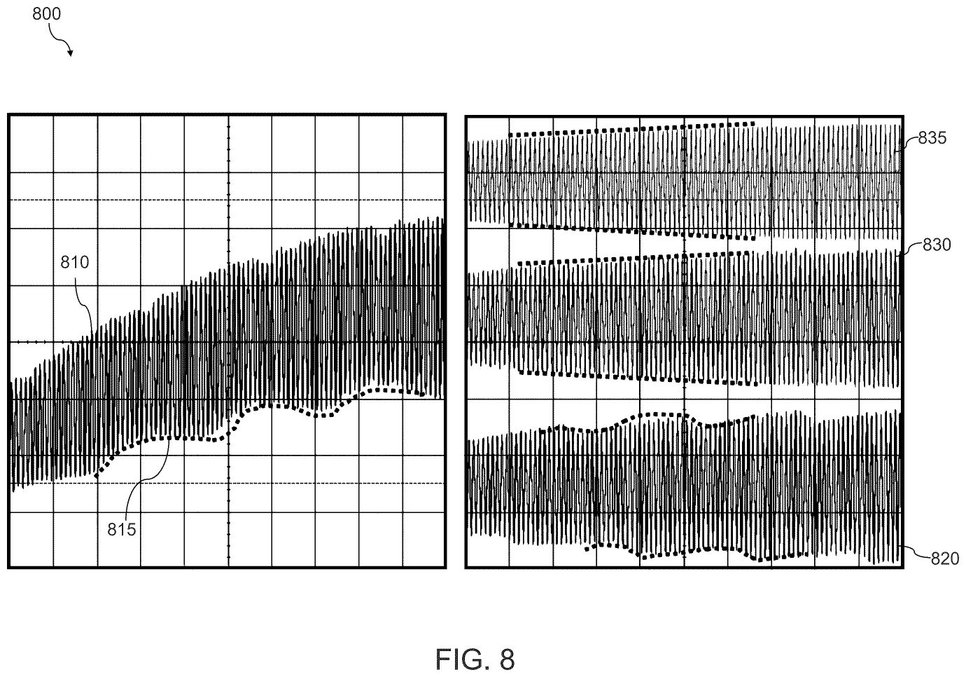

Referring now to FIG. 8, a graphical representation of example signals of an induction heating system according to example embodiments is provided. Specifically, example signals 800 are provided by an induction heating system running multiple (e.g., two) induction coil channels. The coil current is represented by coil current signal 835. Example signal 810 is a voltage signal indicative of a voltage at a measurement node of a first coil, such as at measurement node 310 as shown in FIGS. 3 and 5. As previously described, measurement node 310 may be defined between induction coil 320 and one or more resonant capacitors (e.g., C2 and C3) of induction coil system 300. As shown, the second coil of the induction heating system induces a voltage ripple envelope 815 (e.g., heterodyne effect) in example signal 810.

Example signal 820 is an output signal of differentiation circuit 540 (FIG. 5) when only a single measurement signal is used as an input without noise rejection. Alternatively, example signal 830 is an output signal of noise rejection circuit 500 (FIG. 5).

As shown in FIG. 8, an output of differentiation circuit 540 alone (e.g., example signal 820) may be susceptible to noise induced by a second coil of the induction heating system. Alternatively, the output of a noise rejection circuit as described herein may provide an accurate voltage representation of coil current signal 835.

One example aspect of the present disclosure is directed to an induction heating system for an induction cooking appliance. The induction heating system includes an induction coil system operable to inductively heat a load with an induction coil. The induction heating system further includes a noise rejection circuit configured to determine an output signal indicative of one or more induction coil parameters of the induction coil system based at least in part on a measurement signal indicative of a voltage at a first node of the induction coil system, the first node defined between the induction coil and one or more resonant capacitors of the induction coil system, and one or more noise signals indicative of a voltage at one or more second nodes of the induction coil system.

In some examples, the one or more noise signals include a high-side signal indicative of a high-side voltage of the induction coil system.

In some examples, the one or more noise signals include a high-side signal indicative of a high-side voltage of the induction coil system and a low-side signal indicative of a low-side voltage of the induction coil system.

In some examples, the one or more second nodes include a high-side node defined between a first resonant capacitor of the one or more resonant capacitors and a high-side switching device of the induction coil system, and a low-side node defined between a second resonant capacitor of the one or more resonant capacitors and a low-side switching device of the induction coil system.

In some examples, the noise rejection circuit is configured to determine the output signal indicative of the one or more induction coil parameters by determining a doubled measurement signal by doubling the measurement signal, subtracting the high-side signal from the doubled measurement signal, and subtracting the low-side signal from the doubled measurement signal.

In some examples, the induction heating system further includes a controller operably coupled to the noise rejection circuit and the induction coil system. The controller is configured to process the output signal indicative of one or more induction coil parameters of the induction coil system to determine a power of the induction coil.

In some examples, the induction heating system further includes a controller operably coupled to the noise rejection circuit and the induction coil system. The controller is configured to process the output signal indicative of one or more induction coil parameters of the induction coil system to determine a load presence of the induction coil.

In some examples, the noise rejection circuit includes a summation circuit. The summation circuit is configured to determine a doubled measurement signal by doubling the measurement signal, and determine the output signal by subtracting the one or more noise signals from the doubled measurement signal.

In some examples, the noise rejection circuit further includes a scaling circuit configured to scale the measurement signal and the one or more noise signals, an offset circuit configured to add a direct-current (DC) offset to the one or more noise signals, and a differentiation circuit configured to differentiate the output signal.

Another example aspect of the present disclosure is directed to a method for determining an induction coil parameter in an induction cooking appliance. The method includes determining a measurement signal indicative of a voltage at a first node of an induction coil system of the induction cooking appliance, the first node defined between two resonant capacitors. The method further includes determining one or more noise signals indicative of a voltage at one or more second nodes of the induction coil system. The method further includes determining an output signal indicative of one or more induction coil parameters of the induction coil system based at least in part on the measurement signal and the one or more noise signals.

In some examples, the output signal is a voltage signal representative of a current through an induction coil of the induction coil system.

In some examples, the one or more noise signals include a high-side signal indicative of a high-side voltage of the induction coil system, and a low-side signal indicative of a low-side voltage of the induction coil system.

In some examples, the one or more second nodes include a high-side node defined between a first resonant capacitor of the two resonant capacitors and a high-side switching device of the induction coil system, and a low-side node defined between a second resonant capacitor of the two resonant capacitors and a low-side switching device of the induction coil system.

In some examples, determining the output signal indicative of the one or more induction coil parameters of the induction coil system include determining a doubled measurement signal by doubling the measurement signal, subtracting the high-side signal from the doubled measurement signal, and subtracting the low-side signal from the doubled measurement signal.

In some examples, the method further includes processing the output signal indicative of the one or more induction coil parameters of the induction coil system to determine an output power of the induction cooking appliance.

In some examples, the method further includes processing the output signal indicative of the one or more induction coil parameters of the induction coil system to determine a load presence of the induction cooking appliance.

Another example aspect of the present disclosure is directed to an induction cooking appliance. The induction cooking appliance includes a user interface including one or more user input devices. The induction cooking appliance further includes an induction heating system. The induction heating system includes an induction coil system operable to inductively heat a load with an induction coil. The induction heating system further includes a noise rejection circuit configured to determine an output signal indicative of one or more induction coil parameters of the induction coil system based at least in part on a measurement signal indicative of a voltage at a first node of the induction coil system, the first node defined between the induction coil and one or more resonant capacitors of the induction coil system, and one or more noise signals indicative of a voltage at one or more second nodes of the induction coil system.

In some examples, the output signal is a voltage signal representative of a current through the induction coil of the induction coil system.

In some examples, the one or more noise signals include a high-side signal indicative of a high-side voltage of the induction coil system, and a low-side signal indicative of a low-side voltage of the induction coil system.

In some examples, the noise rejection circuit is configured to determine the output signal indicative of the one or more induction coil parameters by determining a doubled measurement signal by doubling the measurement signal, subtracting the high-side signal from the doubled measurement signal, and subtracting the low-side signal from the doubled measurement signal.

Although specific features of various embodiments may be shown in some drawings and not in others, this is for convenience only. In accordance with the principles of the present disclosure, any feature of a drawing can be referenced and/or claimed in combination with any feature of any other drawing.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. An induction heating system for an induction cooking appliance, comprising:
an induction coil system operable to inductively heat a load with an induction coil;
a noise rejection circuit configured to determine an output signal indicative of one or more induction coil parameters of the induction coil system based at least in part on:
a measurement signal indicative of a voltage at a first node of the induction coil system, the first node defined between the induction coil and one or more resonant capacitors of the induction coil system; and
one or more noise signals indicative of a voltage at one or more second nodes of the induction coil system.

2. The induction heating system of claim 1, wherein the one or more noise signals comprises:
a high-side signal indicative of a high-side voltage of the induction coil system.

3. The induction heating system of claim 1, wherein the one or more noise signals comprise:
a high-side signal indicative of a high-side voltage of the induction coil system; and
a low-side signal indicative of a low-side voltage of the induction coil system.

4. The induction heating system of claim 3, wherein the one or more second nodes comprise:
a high-side node defined between a first resonant capacitor of the one or more resonant capacitors and a high-side switching device of the induction coil system; and
a low-side node defined between a second resonant capacitor of the one or more resonant capacitors and a low-side switching device of the induction coil system.

5. The induction heating system of claim 3, wherein the noise rejection circuit is configured to determine the output signal indicative of the one or more induction coil parameters by:
determining a doubled measurement signal by doubling the measurement signal;
subtracting the high-side signal from the doubled measurement signal; and
subtracting the low-side signal from the doubled measurement signal.

6. The induction heating system of claim 1, further comprising:
a controller operably coupled to the noise rejection circuit and the induction coil system,
wherein the controller is configured to process the output signal indicative of one or more induction coil parameters of the induction coil system to determine a power of the induction coil.

7. The induction heating system of claim 1, further comprising:
a controller operably coupled to the noise rejection circuit and the induction coil system,
wherein the controller is configured to process the output signal indicative of one or more induction coil parameters of the induction coil system to determine a load presence of the induction coil.

8. The induction heating system of claim 1, wherein the noise rejection circuit comprises a summation circuit, the summation circuit configured to:
determine a doubled measurement signal by doubling the measurement signal; and
determine the output signal by subtracting the one or more noise signals from the doubled measurement signal.

9. The induction heating system of claim 8, wherein the noise rejection circuit further comprises:
a scaling circuit configured to scale the measurement signal and the one or more noise signals;
an offset circuit configured to add a direct-current (DC) offset to the one or more noise signals; and
a differentiation circuit configured to differentiate the output signal.

10. A method for determining an induction coil parameter in an induction cooking appliance, the method comprising:
determining a measurement signal indicative of a voltage at a first node of an induction coil system of the induction cooking appliance, the first node defined between two resonant capacitors;
determining one or more noise signals indicative of a voltage at one or more second nodes of the induction coil system; and
determining an output signal indicative of one or more induction coil parameters of the induction coil system based at least in part on the measurement signal and the one or more noise signals.

11. The method of claim 10, wherein the output signal is a voltage signal representative of a current through an induction coil of the induction coil system.

12. The method of claim 10, wherein the one or more noise signals comprise:
a high-side signal indicative of a high-side voltage of the induction coil system; and
a low-side signal indicative of a low-side voltage of the induction coil system.

13. The method of claim 10, wherein the one or more second nodes comprise:
a high-side node defined between a first resonant capacitor of the two resonant capacitors and a high-side switching device of the induction coil system; and
a low-side node defined between a second resonant capacitor of the two resonant capacitors and a low-side switching device of the induction coil system.

14. The method of claim 12, wherein determining the output signal indicative of the one or more induction coil parameters of the induction coil system comprises:
determining a doubled measurement signal by doubling the measurement signal;
subtracting the high-side signal from the doubled measurement signal; and
subtracting the low-side signal from the doubled measurement signal.

15. The method of claim 10, further comprising:
processing the output signal indicative of the one or more induction coil parameters of the induction coil system to determine an output power of the induction cooking appliance.

16. The method of claim 10, further comprising:
processing the output signal indicative of the one or more induction coil parameters of the induction coil system to determine a load presence of the induction cooking appliance.

17. An induction cooking appliance, comprising:
a user interface comprising one or more user input devices; and
an induction heating system, comprising:
an induction coil system operable to inductively heat a load with an induction coil;
a noise rejection circuit configured to determine an output signal indicative of one or more induction coil parameters of the induction coil system based at least in part on:
a measurement signal indicative of a voltage at a first node of the induction coil system, the first node defined between the induction coil and one or more resonant capacitors of the induction coil system; and
one or more noise signals indicative of a voltage at one or more second nodes of the induction coil system.

18. The induction cooking appliance of claim 17, wherein the output signal is a voltage signal representative of a current through the induction coil of the induction coil system.

19. The induction cooking appliance of claim 17, wherein the one or more noise signals comprise:
a high-side signal indicative of a high-side voltage of the induction coil system; and
a low-side signal indicative of a low-side voltage of the induction coil system.

20. The induction cooking appliance of claim 19, wherein the noise rejection circuit is configured to determine the output signal indicative of the one or more induction coil parameters by:
determining a doubled measurement signal by doubling the measurement signal;
subtracting the high-side signal from the doubled measurement signal; and
subtracting the low-side signal from the doubled measurement signal.
